(19) United States
(12) Patent Application Publication
(10) Pub. No.: US 2025/0176444 A1
(43) Pub. Date: May 29, 2025

(54) MICRO PHASE CHANGE ACTUATOR MANUFACTURING METHOD, MICRO PHASE CHANGE ACTUATOR, MICRO PHASE CHANGE ACTUATOR ARRAY MANUFACTURING METHOD, MICRO PHASE CHANGE ACTUATOR ARRAY, AND TACTILE DISPLAY

(71) Applicant: UIF (University Industry Foundation), Yonsei University, Seoul (KR)

(72) Inventors: Jong Baeg KIM, Goyang-si (KR); Kyu Bin BAE, Seoul (KR); Sang Jun SIM, Seoul (KR)

(73) Assignee: UIF (University Industry Foundation), Yonsei University, Seoul (KR)

(21) Appl. No.: 18/952,144

(22) Filed: Nov. 19, 2024

(30) Foreign Application Priority Data
Nov. 28, 2023 (KR) 10-2023-0167664
Oct. 29, 2024 (KR) 10-2024-0149187

(51) Int. Cl. H10N 70/20; H10N 70/00; H10N 79/00

(52) U.S. Cl. CPC H10N 70/231; H10N 70/021; H10N 70/041; H10N 79/00

(57) ABSTRACT

A method for manufacturing a micro phase-change actuator, a micro phase-change actuator manufactured thereby, a method for manufacturing a micro phase-change actuator array, a micro phase-change actuator array manufactured thereby, and a tactile display including the same are disclosed. The method for manufacturing the micro phase-change actuator includes a first step of selectively forming a droplet of a phase-change material on a microheater formed on a substrate; a second step of freezing the droplet selectively formed on the microheater; and a third step of forming a stretchable membrane so as to seal at least the frozen droplet.

### CROSS-REFERENCE TO RELATED APPLICATION

This application claims priority to Korean Patent Application No. 10-2023-0167664 filed on Nov. 28, 2023, and Korean Patent Application No. 10-2024-0149187 filed on Oct. 29, 2024, and all the benefits accruing therefrom under 35 U.S.C. 119, the contents of each of which are herein incorporated by reference in their entirety.

### BACKGROUND

### Field

The present disclosure relates to a method for manufacturing a micro phase-change actuator, a micro phase-change actuator, a method for manufacturing a micro phase-change actuator array, a micro phase-change actuator array, and a tactile display.

### Description of Related Art

Development of a flexible tactile display has been based on an actuator array with various mechanisms. Various mechanisms may include electromagnetic, electrostatic, and pneumatic actuating schemes. The flexible tactile display utilizing an electrostatic actuator developed through a previous study has a fast response speed of 5 ms and exhibits a force of 300 mN. However, a size of a single actuator in the flexible tactile display is 6 mm, thereby causing limitations in the transmission of complex tactile information to a fingertip. Furthermore, the previous study demonstrated that the flexible haptic device using the pneumatically actuating scheme exhibited a large actuating displacement of 1 mm or greater. However, it is difficult for a user to use the flexible haptic device using the pneumatically actuating scheme without space constraints because additional devices such as a pump and a valve are required to control each cell.

### SUMMARY

In contrast thereto, the present disclosure may provide a method for manufacturing a flexible actuator with a single cell diameter and thickness of several hundred micrometers using a micro-scale liquid-gas or solid-liquid phase change actuator in a batch manufacturing process. This actuator exhibits a large actuating displacement even at a low power level and a fast response time of several hundred milliseconds, such that the actuator is used in the tactile display that transfers complex and sophisticated tactile sensations to the user.

A conventional actuator has a large size and a heavy weight which limits application thereof to various shapes and surfaces, and has poor durability, which makes it difficult to maintain stable performance for a long period of time.

Thus, a purpose of the present disclosure is to provide a method for manufacturing a small micro actuator in a rapid and simple manner by enabling accurate positioning of a phase-change material via selective hydrophilic treatment.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A first aspect of the present disclosure provides a method for manufacturing a micro phase-change actuator, the method comprising: a first step of selectively forming a droplet of a phase-change material on a microheater formed on a substrate; a second step of freezing the droplet selectively formed on the microheater; and a third step of forming a stretchable membrane so as to seal at least the frozen droplet.

According to some embodiments of the method for manufacturing the micro phase-change actuator, the first step includes selectively performing a hydrophilic treatment on the microheater and then applying a hydrophilic phase-change material thereon.

According to some embodiments of the method for manufacturing the micro phase-change actuator, the hydrophilic treatment on the microheater includes applying oxygen plasma to the microheater.

According to some embodiments of the method for manufacturing the micro phase-change actuator, the hydrophilic treatment on the microheater includes applying oxygen plasma to the microheater while masking a portion of the substrate except for the microheater, thereby selectively performing hydrophilic treatment on the microheater.

According to some embodiments of the method for manufacturing the micro phase-change actuator, the first step includes forming frozen phase-change material particles on the microheater formed on the substrate; activating the microheater to melt the frozen phase-change material particles into droplets of the phase-change material; and selectively merging the droplets on the microheater with each other.

According to some embodiments of the method for manufacturing the micro phase-change actuator, the substrate is embodied as a flexible substrate.

According to some embodiments of the method for manufacturing the micro phase-change actuator, the stretchable membrane on the frozen droplet is formed to have a wrinkled structure.

A second aspect of the present disclosure provides a method for manufacturing a micro phase-change actuator array according to an embodiment of the present disclosure, the method including a first step of selectively forming droplets of a phase-change material on a plurality of microheaters formed on a substrate; a second step of freezing the droplets selectively formed on the plurality of microheaters; and a third step of forming a stretchable membrane so as to seal the plurality of frozen droplets.

According to some embodiments of the method for manufacturing the micro phase-change actuator array, the substrate is embodied as a hydrophobic substrate.

According to some embodiments of the method for manufacturing the micro phase-change actuator array, in the second step, the shape of each of the droplets may be maintained via the freezing.

According to some embodiments of the method for manufacturing the micro phase-change actuator array, the first step includes selectively performing a hydrophilic treatment on the plurality of microheaters and then applying a hydrophilic phase-change material thereon.

According to some embodiments of the method for manufacturing the micro phase-change actuator array, each of the plurality of microheaters has a size of about 1 mm or smaller.

According to some embodiments of the method for manufacturing the micro phase-change actuator array, the hydrophilic treatment on the microheaters includes applying oxygen plasma to the microheaters.

According to some embodiments of the method for manufacturing the micro phase-change actuator array, the hydrophilic treatment on the microheaters includes applying oxygen plasma to the microheaters while masking a portion of the substrate except for the microheaters, thereby selectively performing the hydrophilic treatment on the microheaters.

According to some embodiments of the method for manufacturing the micro phase-change actuator array, the first step includes forming frozen phase-change material particles on each of the plurality of microheaters formed on the substrate; activating the plurality of microheaters to melt the frozen phase-change material particles on each of the plurality of microheaters into droplets of the phase-change material; and selectively merging the droplets on each of the microheaters with each other.

According to some embodiments of the method for manufacturing the micro phase-change actuator array, the substrate is embodied as a flexible substrate.

According to some embodiments of the method for manufacturing the micro phase-change actuator array, the stretchable membrane on the frozen droplet is formed to have a wrinkled structure.

A third aspect of the present disclosure provides a micro phase-change actuator manufactured by the method of the first aspect.

A fourth aspect of the present disclosure provides a micro phase-change actuator array manufactured by the method of the second aspect.

A fifth aspect of the present disclosure provides a tactile display including the micro phase-change actuator array of the fourth aspect.

The micro actuator of the present disclosure is miniaturized and flexible, and thus has high applicability to various fields, and the micro actuator manufacturing method of the present disclosure enables rapid manufacturing of the small and flexible micro actuator in a simple process.

In addition to the effects as described above, specific effects in accordance with the present disclosure will be described together with following detailed descriptions for carrying out the disclosure.

### BRIEF DESCRIPTION OF DRAWINGS

FIG. 1 illustrates a manufacturing method, a structure, and an operation principle of a micro phase-change flexible actuator of the present disclosure.

FIG. 2A is a diagram showing change in a height of a micro phase-change actuator based on a power level applied to the actuator.

FIG. 2B is a diagram showing a driving force and a state change of a micro phase-change actuator based on a varying power level.

FIG. 2C is a diagram showing a displacement (μm) of a micro phase-change actuator based on an input power level (mW).

FIG. 2D is a diagram showing change in a displacement over time and a response speed in an ON/OFF state of the micro phase-change actuator.

FIG. 2E is a diagram showing change in a displacement of a micro phase-change actuator under various frequency conditions (Hz).

FIG. 3 shows applicability of a flexible phase-change actuator to a tactile display.

FIG. 4A and FIG. 4B are diagrams showing a manufacturing process of a micro phase-change actuator.

### DETAILED DESCRIPTIONS

Hereinafter, embodiments of the present disclosure will be described in detail with reference to the accompanying drawings. The present disclosure may be subjected to various changes and may have various forms. Thus, particular embodiments will be illustrated in the drawings and will be described in detail herein. However, this is not intended to limit the present disclosure to a specific disclosed form. It should be understood that the present disclosure includes all modifications, equivalents, and replacements included in the spirit and technical scope of the present disclosure. While describing the drawings, similar reference numerals are used for similar components.

Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

For simplicity and clarity of illustration, elements in the drawings are not necessarily drawn to scale. The same reference numbers in different drawings represent the same or similar elements, and as such perform similar functionality. A shape, a size, a ratio, an angle, a number, etc. disclosed in the drawings for illustrating embodiments of the present disclosure are illustrative, and the present disclosure is not limited thereto.

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or some thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In descriptions of temporal relationships, for example, temporal precedent relationships between two events such as “after”, “subsequent to”, “before”, etc., another event may occur therebetween unless “directly after”, “directly subsequent” or “directly before” is not indicated.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof. In the context of the present disclosure, the term “about” may mean about ±1%, about ±2%, about ±3%, about ±4%, about ±5%, about ±6%, about ±7%, about ±8%, about ±9%, or about ±10% of a value stated herein.

A method for manufacturing a micro phase-change actuator according to an embodiment of the present disclosure includes: a first step of selectively forming a droplet of a phase-change material on a microheater formed on a substrate; a second step of freezing the droplet selectively formed on the microheater; and a third step of forming a stretchable membrane so as to seal at least the frozen droplet.

A role of the first step is to selectively form the phase-change material only on the microheater, thereby helping to accurately define a working position of the phase-change actuator. The meaning of selectively forming the droplet on the microheater formed on the substrate means that the droplet is formed on the microheater, and the droplet is not formed on an area of the substrate other than an area thereof where the microheater is formed. The role of the second step is to freeze the droplet of the phase-change material formed on the microheater, thereby helping to stably maintain the phase-change material. The freezing prevents the position and shape of the phase-change material from being changed. A role of the third step is to cover and seal the frozen phase-change material with the stretchable membrane.

In one embodiment, the first step may include selectively performing a hydrophilic treatment on the microheater and then applying a hydrophilic phase-change material thereon. In this regard, the first step includes a step of selectively performing a hydrophilic treatment on the microheater formed on the substrate. A role of this step is to modify the surface of the microheater using a specific chemical scheme (e.g., applying oxygen plasma) to impart hydrophilicity thereto. This allows the phase-change material to be effectively attached to the surface of the microheater. In the second step, a process of forming a droplet of a hydrophilic phase-change material (e.g., water) on the microheater and maintaining the shape of the droplet is performed. In this process, the phase-change material may be converted to a solid state to form a stable structure, which may be used in a subsequent step. Finally, the third step is a process of forming a stretchable membrane to seal the droplet whose the shape is maintained. This stretchable membrane may surround the phase-change material to provide physical protection and flexibly respond to deformation that may occur during actuation of the actuator. In one embodiment, the shape of the droplet in the second step may be maintained via freezing.

In the context of the present disclosure, the meaning of the hydrophilic treatment means a process of changing the properties of the surface of the microheater or another portion so that a liquid such as water may easily adhere to the surface. This treatment may increase hydrophilicity by changing the chemical or physical properties of the surface. In general, the hydrophilic treatment may be performed by using a specific chemical substance or applying a specific treatment to the surface. For example, a hydrophilic group may be introduced to the surface through a process such as oxygen plasma application, or a roughness of a surface of a hydrophilic substrate may be increased to increase hydrophilicity thereof. Such hydrophilic treatment may play an important role in a manufacturing process of the micro phase-change actuator. In particular, the hydrophilic treatment may be selectively performed on the microheater formed on the substrate in the first step, such that the hydrophilic phase-change material may be effectively attached only to a specific area of the microheater. This enables precise positioning of the phase-change material, and thus improves the overall performance and efficiency of the actuator.

In one embodiment, the hydrophilic treatment may include applying oxygen plasma to the microheater. This scheme is an effective scheme of changing the chemical properties of the microheater surface to impart hydrophilicity thereto. The oxygen plasma treatment causes a fine structural change on the surface, thereby making the surface more reactive to a liquid such as water. The microheater surface with increased hydrophilicity allows better attachment of the phase-change material droplet thereto. This scheme is a relatively simple and efficient scheme, and may be easily applied in the mass production process, and is advantageous for the large-scale manufacturing and commercialization of the micro phase-change actuator. In one embodiment, the hydrophilic treatment may be selectively performed on the microheater by performing oxygen plasma application thereon while masking a portion of the substrate except for the microheater. This scheme enables a precise process of imparting hydrophilicity only to a specific area. The masking may prevent the hydrophilicity from being imparted to an unnecessary area and may allow the hydrophilicity to be concentrated only on the necessary microheater area. This allows the phase-change material to be precisely attached only to the microheater area.

In one embodiment, the droplet may be formed by applying the hydrophilic phase-change material on the microheater formed on a hydrophobic substrate and on the hydrophobic substrate and then selectively removing a portion of the hydrophilic phase-change material formed on the substrate. This scheme may be effective in precisely positioning the hydrophilic phase-change material on the microheater. Through the selective removal process, the phase-change material remains only in the necessary area, thereby enabling precise and rapid manufacturing of the micro phase-change actuator. This process may allow the actuator with complex pattern or design to be manufactured, and thus to be applied to in more sophisticated and diverse applications.

In one embodiment, the substrate may be a hydrophobic substrate. In the context of the present disclosure, the hydrophobic substrate means a substrate made of a material having properties that minimize interaction with a hydrophilic substance such as water. The water or other liquids may be prevented from being easily attached to the surface of the substrate so that liquids may be easily removed therefrom. This hydrophobic property may play an important role in the manufacturing process of the micro phase-change actuator. In particular, the hydrophilic treatment may be performed on the microheater in the first step. Thus, the properties of the hydrophobic substrate may play an important role in effectively attaching the hydrophilic phase-change material only to the microheater. In this way, precise positioning of the phase-change material may be achieved.

In one embodiment, the first step may include forming frozen phase-change material particles on the microheater formed on the substrate; activating the microheater to melt the frozen phase-change material particles into droplets of the phase-change material; and selectively merging the droplets on the microheater with each other. This scheme enables controlled positioning of the phase-change material, and the droplets may be naturally merged with each other during the melting process such that the larger single merged droplet may be precisely positioned on the microheater. This scheme will be described in detail with reference to an example.

In one embodiment, the substrate may be embodied as a flexible substrate. The use of the flexible substrate greatly expands the application range of the micro phase-change actuator. The flexible substrate may be bent or applied to various shaped surfaces, thereby enabling use thereof in various fields such as wearable technology, flexible displays, and medical devices. Furthermore, the flexible substrate allows the actuator to have higher durability against physical stress or deformation. The higher durability may be important for reliability and performance maintenance in long-term use. Therefore, the use of the flexible substrate has the potential to increase the structural diversity and functional flexibility of the micro phase-change actuator, thereby creating a wider range of applications and innovative use cases.

In one embodiment, the stretchable membrane on the frozen droplet may be formed to have a wrinkled structure. In the context of the present disclosure, the term “wrinkled structure” refers to a state in which fine wrinkles or corrugation are formed on the surface, and may serve to increase the flexibility of the mechanical deformation. This structure may allow the stretchable membrane to effectively respond to the volume change that occurs in the phase-change process and contribute to generating a larger displacement.

In the context of the present disclosure, the term microheater refers to a device or a component that has a small size and generates heat. The microheater may play an important role mainly in the micro phase-change actuator, and may be used to heat the phase-change material to cause a state change thereof. The main function of the microheater is to change a state of the phase-change material (e.g., water or paraffin) from a liquid state to a gaseous state, or from a solid to a liquid state. Thus, the microheater causes a pressure change in the actuator, thereby causing deformation of the stretchable membrane and mechanical movement of the actuator. The design and size of the microheater may vary depending on the application and required performance of the actuator. Typically, the microheater may have a very small size (e.g., smaller than or equal to 1 mm) and may be designed to be precisely controlled.

In one embodiment, the microheater may have a size of about 1 mm or smaller. This miniaturization may allow the micro phase-change actuator to be applied to various applications. The small-sized microheater is space-efficient and enables precise thermal control, thereby enhancing the reactivity of the phase-change material. This may play an important role, especially in miniature electronic devices, precision medical devices, and industrial fields that require highly precise adjustment. Furthermore, the microheater may allow the small-sized actuator to achieve more precise movement and higher response speed which are increasingly required in modern society where miniaturization technology is increasingly demanded. However, the size of the microheater does not limit the scope of the present disclosure.

In one embodiment, in the second step, the shape of the droplet may be maintained via freezing.

In the context of the present disclosure, the phase-change material means a material whose a state changes under a varying temperature. The phase-change material used in the micro phase-change actuator is a material that may mainly experience the phase change under the heat, and may undergo the state change when being heated by the microheater. For example, water is used as a general phase-change material, and is vaporized when heat is applied thereto. The vaporized water vapor is cooled and condensed. The phase-change material having the above properties may play a key role in the working principle of the micro phase-change actuator. When being heated by the microheater, the phase-change material is converted from a liquid state to a gaseous state or from a solid state to a liquid state such that the volume expands, thereby causing the stretchable membrane to be deformed to generate the movement of the actuator. Conversely, when the heat source is removed, the phase-change material returns to its original state, and thus, the deformed membrane may be restored to its original state. This process may allow the micro phase-change actuator to be precisely controlled and to have accurate responsiveness, and may enable fine adjustment and precise movement, especially in applications such as the tactile display.

In the context of the present disclosure, the droplet means a small liquid drop. In the second and third steps, the phase-change material droplet may be maintained in its shape via the freezing, and then the shape-maintained droplet may be covered with the stretchable membrane to physically isolate and protect the droplet. This stretchable membrane may prevent the shape-maintained droplet from being affected by the external environment, and may respond to the pressure and mechanical deformation that occur during the operation of the micro phase-change actuator. The shape-maintained droplet may be sealed with the stretchable membrane, such that the volume change and pressure change that occur when the phase-change material is heated and cooled under the operation of the microheater may be used as useful kinetic energy of the stretchable membrane. These volume and pressure changes generate the movement of the actuator.

In one embodiment, in the third step, the stretchable membrane may be formed at a low temperature where the droplet remains in the frozen state. This allows the formation of the stretchable membrane while the position of the droplet is precisely fixed. This scheme may cause the phase-change material to be more precisely controlled, thereby contributing to the performance stability of the actuator. Furthermore, when the third step is performed while the droplet is maintained in the frozen state, the sensitivity of the phase-change material to the temperature change in the external environment may be lowered to some extent, thereby helping increase the reliability of the actuator in various application environments. In this way, the overall life and efficiency of the actuator may be improved.

In the context of the present disclosure, the stretchable membrane is generally made of a flexible material, so that the stretchable membrane may flexibly respond to the volume change that occurs due to the state change of the phase-change material. This membrane may play an important role in absorbing the pressure change that occurs when the phase-change material vaporizes or condenses, and converting the pressure change into mechanical movement of the actuator.

As described above, the micro phase-change actuator may be manufactured through the first to third steps, such that the manufactured actuator may be miniaturized and have flexibility so as to be applied to various shapes and surfaces. Furthermore, durability and reliability thereof may be enhanced, so that the actuator may provide stable performance for a long time. Thus, the micro phase-change actuator may be applicable to various high-precision applications such as tactile displays, microfluidic control, robotics, and medical equipment, and may provide high technical value and innovative solutions.

In one example, the micro phase-change actuator according to an embodiment of the present disclosure may be manufactured using the method for manufacturing the micro phase-change actuator as described above. This method includes a process of selectively forming the droplet of the phase-change material on the microheater formed on the substrate, a process of freezing the droplet to maintain the shape thereof, and a process of sealing the droplet whose the shape is maintained with the stretchable membrane.

Further, a method for manufacturing a micro phase-change actuator array according to an embodiment of the present disclosure includes a first step of selectively forming droplets of a phase-change material on a plurality of microheaters formed on a substrate; a second step of freezing the droplets selectively formed on the plurality of microheaters; and a third step of forming a stretchable membrane so as to seal the plurality of frozen droplets.

In one embodiment, the plurality of microheaters may be arranged in an array. In the context of the present disclosure, the array means a set of arranged components. In this case, the array may mean a form in which the microheaters are precisely arranged. In such an array structure, the microheaters may operate independently or in combination with each other to generate a complex pattern or reaction.

In one embodiment, the first step may include selectively performing a hydrophilic treatment on the plurality of microheaters and then applying the hydrophilic phase-change material thereon.

In one embodiment, the hydrophilic treatment may include applying oxygen plasma while masking an area of the substrate excluding the plurality of microheaters, thereby selectively performing the hydrophilic treatment on the plurality of microheaters. In one embodiment.

In one embodiment, the first step may include forming frozen phase-change material particles on each of the plurality of microheaters formed on the substrate; activating the plurality of microheaters to melt the frozen phase-change material particles on each of the plurality of microheaters into droplets of the phase-change material; and selectively merging the droplets on each of the microheaters with each other.

In one embodiment, each of the plurality of microheaters may have a size of about 1 mm or smaller. In one embodiment, the hydrophilic treatment includes applying oxygen plasma. In one embodiment, the substrate may be prepared as a flexible substrate. In one embodiment, in the second step, the shapes of the plurality of droplets may be maintained through freezing.

Furthermore, the micro phase-change actuator array according to an embodiment of the present disclosure may cause the phase-change material to experience the liquid-gas phase-change in an actual operating environment. The liquid-gas phase-change may cause relatively large volume expansion, and thus may be advantageous in obtaining a larger displacement in the small actuator. This micro phase-change actuator array may be utilized in various applications such as a tactile display or a wearable device that requires sensitive response of the actuator. This micro phase-change actuator array may have improved performance and may be miniaturized.

As long as the material of the phase-change material has a liquid state in a typical operating environment and vaporizes under appropriate heating thereof, the material of the phase-change material is not particularly limited. Non-limiting examples of the phase-change material may include water, hexane, heptane, petroleum ether, isopropanol, methanol, ethanol, acetone, dimethyl ether, propane, butane, ethyl ether, toluene, xylene, benzene, chloroform, dichloromethane, methylene chloride, methyl acetate, ethyl acetate, acetic acid, diethyl ether, naphtha, propylene glycol, dimethyl sulfoxide (DMSO), cyclohexane, methyl isobutyl ketone, acetonitrile, benzoic acid, isobutyl alcohol, chlorobenzene, trichloroethylene, tetrachloroethylene, tetrahydrofuran, butyl acetate, cyclohexanone, pentane, isooctane, carbonate, octane, butyl alcohol, formic acid, propionic acid, acetaldehyde, phenol, Examples include phthalic anhydride, cyclopentane, xylene, propionaldehyde, isobutane, or combinations of two or more thereof.

In one example, the micro phase-change actuator array according to an embodiment of the present disclosure may be manufactured using the method for manufacturing the micro phase-change actuator array as described above.

In one example, the tactile display according to an embodiment of the present disclosure may include the micro phase-change actuator array. In the context of the present disclosure, the tactile display means a device which allows a user to perceive information through haptic sense. Such a tactile display may transmit various textures, pressures, or temperature changes to the user's skin using the micro phase-change actuator array. Using the micro phase-change actuator array, the tactile display may provide more detailed and precise tactile feedback, thereby greatly improving the user experience in virtual reality, wearable technology, robotics, medical rehabilitation, etc. Furthermore, the tactile display may provide a more immersive interaction with the user, and may be usefully used in a situation where visual or auditory information is not available.

In addition, the micro phase-change actuator or the micro phase-change actuator array according to an embodiment of the present disclosure may be applicable to various applications. These applications may include providing realistic user experiences in virtual reality (VR) and augmented reality (AR) devices, controlling fine movements and textures in precision medical devices, providing delicate manipulation and feedback in robotics, and providing customized haptic feedback in wearable technology. Furthermore, the micro phase-change actuator or the micro phase-change actuator array according to an embodiment of the present disclosure may be applicable to in fields such as touch-based interfaces in automotive interiors, for enhancing user interaction in smart home devices, and providing multimodal feedback in education and training simulations. In these various applications, the micro phase-change actuator may innovatively improve the user experience and contribute to making the interaction between the real world and the digital world more natural and intuitive.

Hereinafter, examples of the present disclosure are described in detail. However, the examples as described as set forth below are only some embodiments of the present disclosure, and the scope of the present disclosure is not limited to the examples as set forth below.

The present disclosure provides a micro phase-change flexible actuator and a method for manufacturing the same.

FIG. 1 shows a fabrication method, a structure, and an operating principle of the micro phase-change flexible actuator of the present disclosure. A micro heater array is patterned on a PI substrate manufactured by a spin-coating process through photolithography, sputtering, and lift-off processes. A hydrophilic treatment is selectively applied to only the heaters using O₂ plasma treatment and a photoresist mask. Thereafter, a phase-change material (water) is selectively patterned on each micro heater of the array through a dip-coating process. The phase-change material is solidified through a freezing process, and a polymer used as the actuator membrane is then spin-coated thereon. Finally, the membrane is hardened and peeled off from a portion of a dummy Si wafer to complete the fabrication. As shown in the optical image, the fabricated actuator exhibits flexibility such that the actuator may be bent without difficulty, and a single cell is manufactured to have a size of several hundred micrometers. The operating principle is based on the phase-change of the working fluid under the heat. When the micro heater generates the heat, the liquid phase-change material vaporizes, thereby deforming the membrane deposited on the phase-change material to induce the displacement. When the heater is turned off, the phase-change material liquefies again, thereby reducing the displacement. In other words, a vertical displacement may be induced under the heater operation.

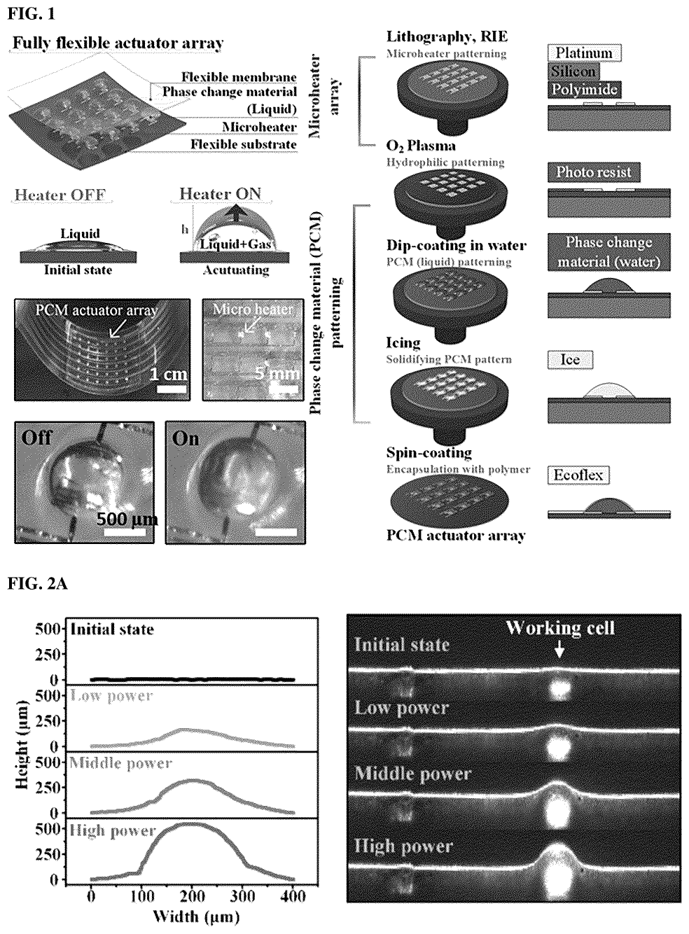

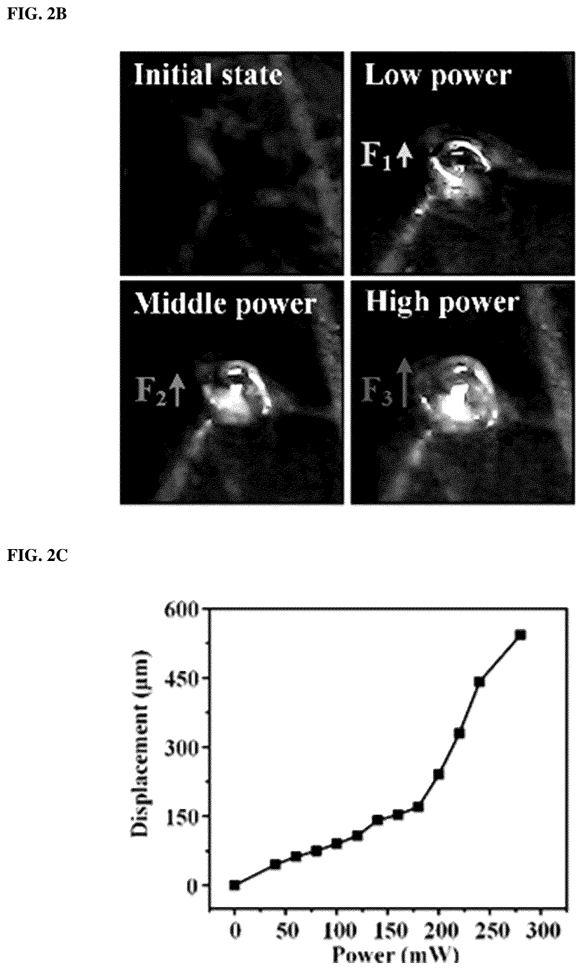

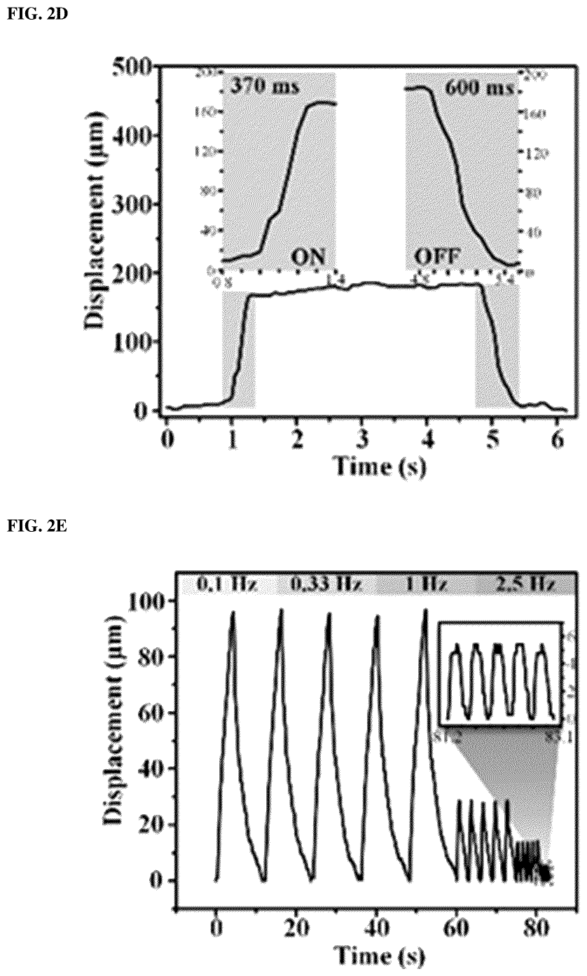

FIG. 2A is a diagram showing change in a height of the micro phase-change actuator based on a power level applied to the actuator. Referring to FIG. 2A, in an initial state, there is almost no deformation of the actuator surface. However, as the power level is changed from a low level to a medium level to a high level, the height of the actuator gradually increases. As the power level increases, the height of the actuator reaches a maximum of about 500 μm, and a width of the actuator increases. It may be identified that under the stepwise change in the height and width of the actuator based on the varying power level, the operation of the actuator may be precisely controlled by adjusting the power level. In FIG. 2A, it may be identified that the displacement of the micro phase-change actuator of the present disclosure may be controlled based on the power level, and that at the high power level, a larger displacement of the actuator may be induced. Thus, the actuator may be applied to applications requiring the precise application.

FIG. 2B is a diagram showing a driving force and a state change of the micro phase-change actuator based on a power level change. Referring to FIG. 2B, there is no change in the actuator in the initial state. However, it may be identified that as the power level changes from a low level to a medium level to a high level, the phase-change material inside the actuator expands such that the driving force increases. At a low power level, a small expansion occurs inside the actuator, thereby generating a force of F1. At a medium power level, a larger force of F2 is generated, further increasing the expansion of the actuator. At a high power level, the maximum expansion occurs, thereby generating a strong force of F3, such that the deformation of the actuator is the largest. In FIG. 2B, it may be identified that the micro phase-change actuator of the present disclosure may finely control the size of the driving force based on the power level, and thus, precise driving force control is achieved.

FIG. 2C is a diagram showing the displacement (μm) of the micro phase-change actuator based on the input power level (mW). Referring to FIG. 2C, the displacement of the actuator tends to increase proportionally as the power level increases. A small displacement occurs at a power level of about 50 mW. When the power level increases to 100 mW or higher, the displacement becomes noticeably larger. When the power level reaches 300 mW, a maximum displacement of about 500 μm is achieved. Through FIG. 2C, it may be identified that the micro phase-change actuator of the present disclosure may effectively control the displacement based on the power level, thereby precisely controlling the displacement according to various operating environments.

FIG. 2D is a diagram showing change in a displacement over time of the micro phase-change actuator and a response speed in the ON/OFF state thereof. Referring to FIG. 2D, when the actuator is turned (ON), the displacement reaches the maximum displacement of about 200 μm within about 370 ms. When the actuator is switched to an off state, the displacement returns to the original state after about 600 ms. A response time of the actuator in the ON/OFF operation indicates the increase and decrease of the displacement that occurs as the phase-change occurs due to the heat. Through FIG. 2D, it may be identified that the micro phase-change actuator of the present disclosure has a relatively fast response speed and may stably operate within a short time after the actuator is turned on.

FIG. 2E is a diagram showing change in a displacement of the micro phase-change actuator under various frequency conditions (Hz). Referring to FIG. 2E, it may be identified that the displacement change of the actuator is repeated at frequencies of 0.1 Hz, 0.33 Hz, 1 Hz, and 2.5 Hz. As the frequency increases, the displacement change frequency of the actuator also increases. In particular, at 2.5 Hz, the displacement of the actuator is maintained at a high frequency. The inserted drawing shows the displacement at the high frequency in more detail. It may be identified based on the inserted drawing that the displacement maintains a constant pattern. Through FIG. 2E, it may be identified that the micro phase-change actuator of the present disclosure may stably operate at various frequencies, and the displacement thereof may be accurately controlled in a high-frequency environment.

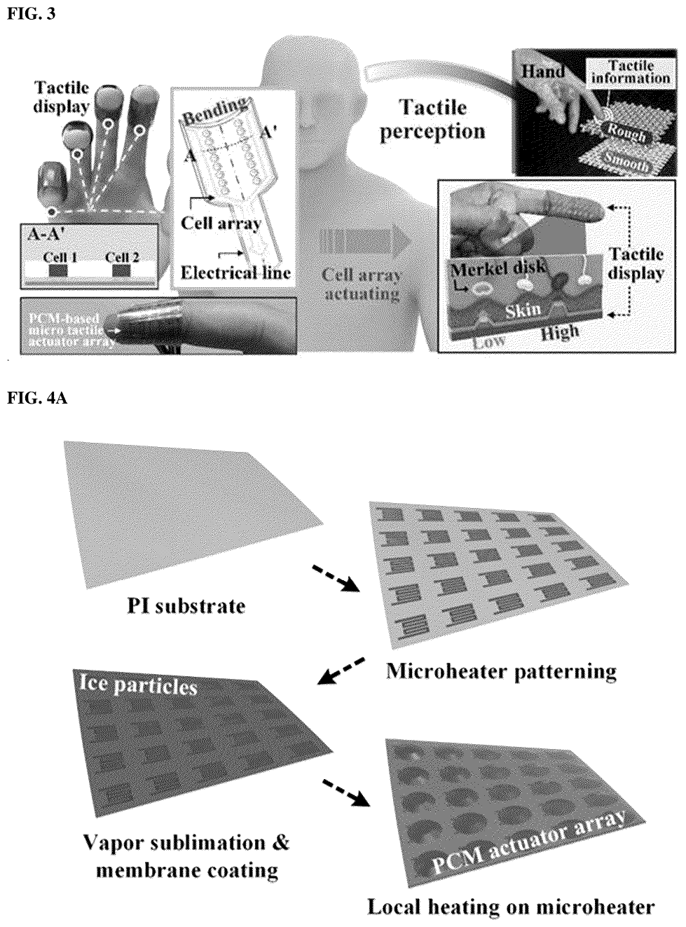

FIG. 3 shows applicability of the flexible phase-change actuator to the tactile display. The phase-change flexible actuator manufactured by the method presented in the present disclosure may be applied to a tactile display device for a haptic interface. The device as shown in FIG. 3 may be closely attached to a curved surface such as a human finger, so that each actuation cell may transmit stimulation while remaining in close contact with the finger. In addition, the device may transmit high-resolution and precise tactile signals at a level at which a person may sufficiently feel the stimulation.

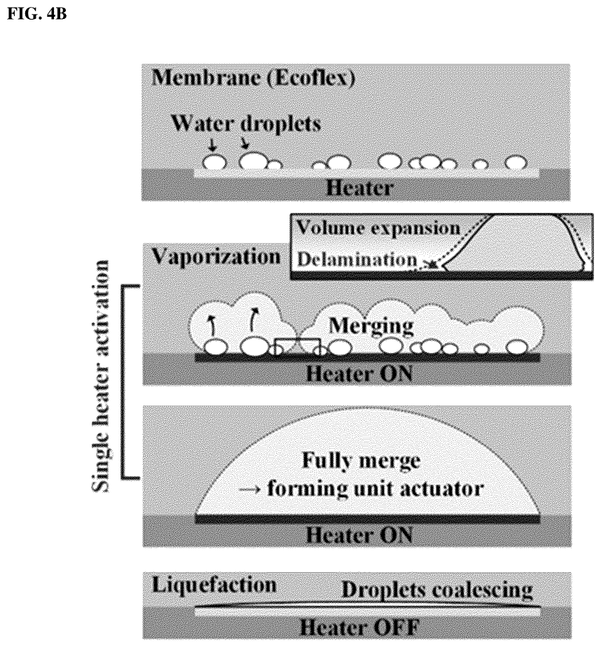

FIG. 4A and FIG. 4B are diagrams showing a manufacturing process of the micro phase-change actuator. Referring to FIG. 4A, first, microheaters are patterned on the PI substrate, and then ice particles are formed on the substrate through the sublimation process, and then the microheaters are activated to partially heat the ice particles. Through FIG. 4B, the principle of forming the droplet when each microheater is activated may be identified. This shows the process in which the ice particles phase-change into the droplets when the microheater is turned on and thus the droplets are merged with each other. Through FIG. 4A and FIG. 4B, it may be identified that in the micro phase-change actuator of the present disclosure, the droplet may be formed at the exact location under the sublimation of the ice particles and the merging of the droplets.

The advantages of the phase-change flexible actuator as proposed in the present disclosure that are different from those of existing research and inventions are as follows: (1) the actuator may exhibit a great vertical displacement in a microscale and may operate quickly, (2) the fully flexible actuator may be achieved using the polymer and liquid-vapor phase change, (3) the vertical displacement of the actuator may be controlled by controlling the heater heating temperature.

Although the embodiments of the present disclosure have been described above with reference to the accompanying drawings, the present disclosure may not be limited to the embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that the embodiments as described above are not restrictive but illustrative in all respects.

What is claimed is:

1. A method for manufacturing a micro phase-change actuator, the method comprising:
a first step of selectively forming a droplet of a phase-change material on a microheater formed on a substrate;
a second step of freezing the droplet selectively formed on the microheater; and
a third step of forming a stretchable membrane so as to seal at least the frozen droplet.

2. The method for manufacturing the micro phase-change actuator of claim 1, wherein the first step includes selectively performing a hydrophilic treatment on the microheater and then applying a hydrophilic phase-change material thereon.

3. The method for manufacturing the micro phase-change actuator of claim 2, wherein the hydrophilic treatment on the microheater includes applying oxygen plasma to the microheater.

4. The method for manufacturing the micro phase-change actuator of claim 3, wherein the hydrophilic treatment on the microheater includes applying oxygen plasma to the microheater while masking a portion of the substrate except for the microheater, thereby selectively performing hydrophilic treatment on the microheater.

5. The method for manufacturing the micro phase-change actuator of claim 1, wherein the first step includes:
forming frozen phase-change material particles on the microheater formed on the substrate;
activating the microheater to melt the frozen phase-change material particles into droplets of the phase-change material; and
selectively merging the droplets on the microheater with each other.

6. The method for manufacturing the micro phase-change actuator of claim 1, wherein the substrate is embodied as a flexible substrate.

7. The method for manufacturing the micro phase-change actuator of claim 1, wherein the stretchable membrane on the frozen droplet is formed to have a wrinkled structure.

8. A micro phase-change actuator manufactured by the method according to claim 1.

9. A tactile display comprising one or more micro phase-change actuators, each micro phase-change actuator being the micro phase-change actuator according to claim 8.
